(19) United States
(12) Patent Application Publication
(10) Pub. No.: US 2009/0311849 A1
(43) Pub. Date: Dec. 17, 2009

(54) METHODS OF SEPARATING INTEGRATED CIRCUIT CHIPS FABRICATED ON A WAFER

(75) Inventors: Paul S. Andry, Yorktown Heights, NY (US); Bing Dang, Chappaqua, NY (US); Matthew J. Farinelli, Bronx, NY (US); Cornelia K. Tsang, Mohegan Lake, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/140,492

(22) Filed: Jun. 17, 2008

(51) Int. Cl. H01L 21/00

(52) U.S. Cl. 438/464; 257/E21.599

(57) ABSTRACT

Improved methods of separating integrated circuit chips fabricated on a single wafer are provided. In an embodiment, a method of separating integrated circuit chips fabricated on a wafer comprises: attaching a support to a back surface of the wafer; dicing the wafer to form individual integrated circuit chips attached to the support; attaching a carrier comprising a releasable adhesive material to a front surface of the wafer opposite from the back surface; separating the support from the back surface of the wafer; subjecting the carrier to an effective amount of heat, radiation, or both to reduce the adhesiveness of the adhesive material to allow for removal of at least one of the integrated circuit chips from the carrier; and picking up and moving at least one of the integrated circuit chips using a tool configured to handle the integrated circuit chips.

### BACKGROUND OF THE INVENTION

1. Field of the Invention

This invention relates to integrated circuits, and particularly to methods of separating integrated circuit chips fabricated on a wafer.

2. Description of Background

Multiple integrated circuit products, referred to as “chips” or “dies”, are often formed on a larger semiconductive substrate, referred to as a “wafer”, to reduce manufacturing costs while increasing the speed of manufacture as compared to forming each die on a separate wafer. While the wafers utilized for this purpose can be any size or shape, the industry standard has been to use round or substantially round wafers having diameters of, e.g., 4 inches, 6 inches, or 12 inches. Each die formed upon the wafer can be individually packaged and sold as a separate product.

After the fabrication of multiple chips on a wafer, the individual chips can be separated to prepare for packaging. This separation often entails laminating the wafer onto a mount tape, followed by dicing the wafer to separate the individual chips. The mount tape can then be deactivated to release the wafer and allow each chip to be individually picked up by an automation tool for testing and/or packaging. Unfortunately, wafer thicknesses have become very thin, making the dicing and handling of such wafers more complex. Glass support wafers can be used to enable handling of thinned wafers. However, glass dicing can be very expensive and time consuming. In addition, glass edge diffraction can adversely affect the release of the thinned wafer via laser ablation from the glass support wafer. The thin chip edges can also experience damage as a result of collision with the individual glass pieces caused by a shock wave during laser release.

Another drawback of the chip separation process is that deactivation of the mount tape can be time consuming since it often involves separately performing laser ablation on each module formed as a result of the dicing step. A less consuming method that has been used to release the chips from the glass support entails soaking the diced chips in a suitable chemical for dissolving the adhesive of the mount tape. However, the released chips can become mixed up in the chemical such that it is difficult to identify the different chips.

### SUMMARY OF THE INVENTION

The shortcomings of the prior art are overcome and additional advantages are provided through the provision of improved methods of separating the integrated circuit chips fabricated on a single wafer. In one embodiment, a method of separating integrated circuit chips fabricated on a wafer comprises: attaching a support to a back surface of the wafer; dicing the wafer to form individual integrated circuit chips attached to the support; attaching a carrier comprising a releasable adhesive material to a front surface of the wafer opposite from the back surface; separating the support from the back surface of the wafer; subjecting the carrier to an effective amount of heat, radiation, or both to reduce the adhesiveness of the adhesive material to allow for removal of at least one of the integrated circuit chips from the carrier; and picking up and moving at least one of the integrated circuit chips using a tool configured to handle the integrated circuit chips.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1-8 illustrate process steps for separating integrated circuit chips fabricated on a single wafer in accordance with an embodiment described herein; and

FIGS. 9-11 illustrate alternative process steps that can replace the step shown in FIG. 8.

The detailed description explains the preferred embodiments of the invention, together with advantages and features, by way of example with reference to the drawings.

### DETAILED DESCRIPTION OF THE INVENTION

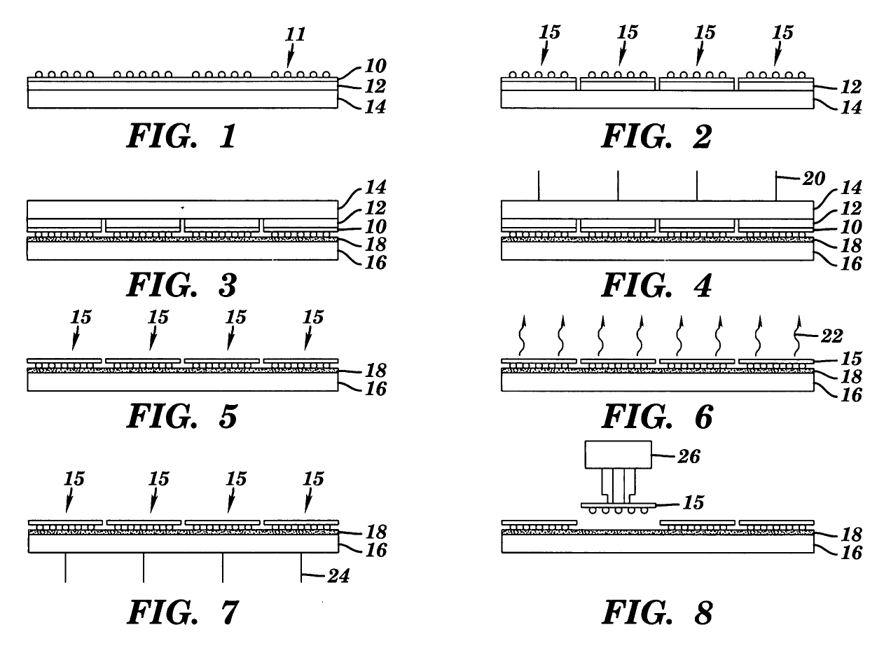

Turning now to the drawings in greater detail, FIG. 1 depicts a cross-sectional view of a semiconductor wafer 10 e.g., a silicon-based wafer, upon which multiple integrated circuit chips have been formed in accordance with current semiconductor fabrication techniques. Conductive bumps 11 can be formed upon the wafer 10 to place the integrated circuit chips in electrical communication with ensuing input/output lines. The wafer 10 can be a thin wafer having a thickness of less than about 200 micrometers (microns), more specifically less than about 100 microns, or even more specifically less than about 50 microns. As shown, a support 14 can be attached to the back surface of the wafer 10 via an adhesive 12 that can adhere well to the back surface of the wafer 10 to hold the support 10 firmly in place during a dicing process. Examples of suitable support materials include but are not limited to glass, quartz, or other transparent substrate materials. The adhesive 12 is desirably a material that is capable of releasing its hold on the support 14 when subjected to heat and/or radiation such as laser ablation. For example, the adhesive 12 can be a spin-on applied adhesive capable of being cured upon the support or target wafer, an adhesive tape or sheet capable of being laminated onto the support or wafer, or a combination comprising at least one of the foregoing adhesives.

The thickness of the adhesive 12 is desirably effective to ensure its retention strength is sufficient to hold the support 14 in place until the adhesive 12 is deactivated. Further, the thicknesses of the adhesive 12 and the support 14 are desirably effective to ensure the support 14 remains intact after the wafer 10 has been diced. For spin-on applied adhesives, the adhesive thickness can be, for example, about 5 microns to about 50 microns, or more specifically about 8 microns to about 12 microns. For adhesive tapes or sheets applied by lamination, the adhesive thickness can be, for example, about 10 microns to 100 microns, or more specifically about 28 to about 32 microns. The support thickness can be, for example, about 500 microns to about 800 microns. More specifically, the support thickness can be similar to that of a standard silicon wafer, e.g., about 730 microns.

Turning to FIG. 2, the integrated circuit chips can be separated by a dicing process designed to cut entirely through the wafer 10 at divisions between the circuit chips while minimally cutting into the support 14 such that it remains intact. Examples of suitable dicing processes include but are not limited to mechanical sawing, scribing and breaking, and laser cutting. As a result of the dicing, the wafer 10 is separated into individual dies 15 attached to support 14. Performing the dicing step in this manner strategically avoids the expense of cutting through a glass support and the resulting damage to the thin integrated circuit chips that could occur.

Subsequent to the dicing process, a carrier 16 comprising a releasable adhesive material 18, e.g., mounting tape, can be attached to a front surface of the wafer 10 (and hence the separated dies 15), as shown in FIG. 3. The adhesive material 18 serves to hold the carrier 16 in place during the subsequent removal of the support 14. The adhesive material 18 is desirably capable of releasing its hold on the carrier 14 upon exposure to an effective amount of heat and/or radiation. In one embodiment, as shown in FIG. 3, the carrier 16 can comprise a component separate from the adhesive material 18. This separate component might be, for example, a plastic, paper, or ceramic material. If desired, this component can be transparent to allow the passage of radiation through it to the adhesive material 18. In another embodiment, the carrier 16 is the adhesive material itself. Examples of suitable adhesive materials include but are not limited to benzocyclobutene, poly(arylene ethers) such as FLARE™ adhesive commercially available from Allied Signal Inc., modified photoresist materials, modified polyimide materials, current thermal release tapes such as Revalpha tape commercially available from Nitto Denko Corporation, and combinations comprising at least one of the foregoing. The thickness of the adhesive material 18 is desirably effective to ensure its retention strength is sufficient to hold the carrier 16 in place until the adhesive material 18 is deactivated. The adhesive thickness can be, for example, about 10 microns to about 100 microns, or more specifically about 28 microns to about 32 microns. Placing the carrier 16 on the front surfaces of the wafer 10 provide for easier handling of the wafer 10 since it increases the thickness of the overall structure.

After adhering the carrier 16 to the individual dies 15 of wafer 10, laser ablation can be applied to the support 14, as indicated by arrows 20 of FIG. 4. The laser ablation is desirably performed by subjecting the support 14 to a pulsed laser beam at a flux capable of carbonizing or vaporizing the adhesive 12, particularly a thin layer of the adhesive 12 closest to the interface being irradiated. The flux can be about 50 to about 200 milliJoules/squared centimeter (mJ/cm²), or more specifically about 80 to 90 mJ/cm². The gaps disposed between laterally adjacent dies 15 form passages through which the gaseous products produced during the laser ablation can escape. Further, the laser ablation advantageously can be performed in a single step since the support 14 remains intact as opposed to the multiple ablations that could be required if the support 14 had been separated into multiple pieces instead. As a result of the laser ablation, the adhesive 12 can release its hold on the support 14, thus allowing the support 14 to be removed from its position adjacent to the dies 15, as shown in FIG. 5. It is to be understood that other forms of heat or radiation also could be used to alter the adhesiveness of adhesive 12. As depicted in FIG. 6, the dies 15 can subsequently be subjected to ashing to remove any material remaining on the back surfaces thereof, as indicated by lines 22. The ashing conditions can be, for example, an oxygen (O₂) flow rate of 200 standard cubic centimeters per minute (sccm), a radition frequency (rf) power of 300 Watts (W), and a pressure of about 200 milliTorr (mTorr).

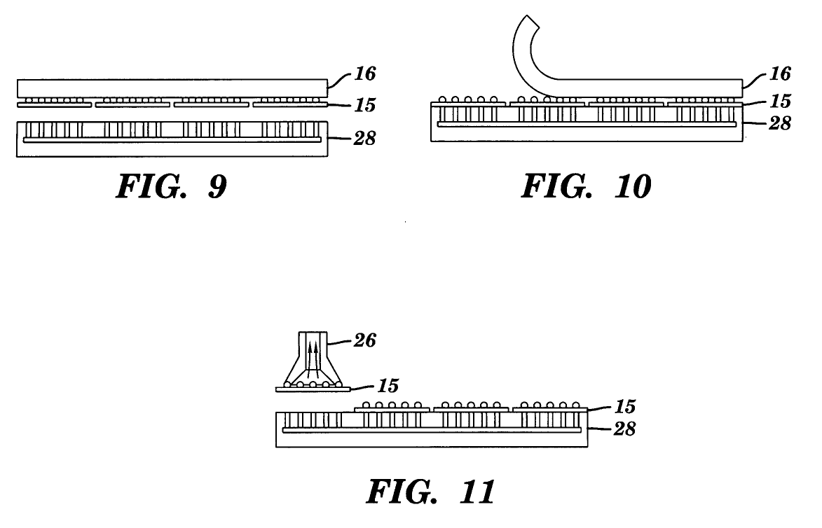

After the ashing step, the adhesive material 18 of the carrier 16 can be subjected to a sufficient amount of heat and/or radiation, e.g., ultra-violet (UV) radiation, as indicated by arrows 24 in FIG. 7, to reduce its adhesiveness such that it no longer adheres to the individual dies 15. By way of example, current thermal tapes can be heated at a temperature of about 50° C. to about 60° C. In the case where UV irradiation is used, the flux can be much less than that used for laser ablation. For example, the adhesive material 18 can be subjected to UV radiation emitted from a standard UV light box for a few minutes. The heat or light can break chemical bonds within the adhesive material 18 such that the material 18 is no longer cohesive. As a result of this altered adhesiveness, the adhesive material 18 releases its hold on the individual dies 15. Consequently, an automated tool 26 can be used to separately pick up and move each die 15 to a desired location such as a testing and/or packaging station, as shown in FIG. 8. In an alternative embodiment shown in FIG. 9, the carrier 16 having the dies 15 attached thereto can be placed on another holder 28 such that the back surfaces of the dies 15 contact the holder 28 prior to removing any of the dies 15. The carrier 16 can then be lifted or peeled off of the dies 15, as illustrated in FIG. 10, to expose the front surfaces of the dies 15. At this point, each die 15 can be separately picked up and moved to a desired location using the automated tool 26, as shown in FIG. 11.

As used herein, the terms “a” and “an” do not denote a limitation of quantity but rather denote the presence of at least one of the referenced items. Moreover, ranges directed to the same component or property are inclusive of the endpoints given for those ranges (e.g., “about 5 wt % to about 20 wt %,” is inclusive of the endpoints and all intermediate values of the range of about 5 wt % to about 20 wt %). Reference throughout the specification to “one embodiment”, “another embodiment”, “an embodiment”, and so forth means that a particular element (e.g., feature, structure, and/or characteristic) described in connection with the embodiment is included in at least one embodiment described herein, and might or might not be present in other embodiments. In addition, it is to be understood that the described elements may be combined in any suitable manner in the various embodiments. Unless defined otherwise, technical and scientific terms used herein have the same meaning as is commonly understood by one of skill in the art to which this invention belongs.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of separating integrated circuit chips fabricated on a wafer, comprising:
attaching a support to a back surface of the wafer;
dicing the wafer to form individual integrated circuit chips attached to the support;
attaching a carrier comprising a releasable adhesive material to a front surface of the wafer opposite from the back surface;
separating the support from the back surface of the wafer;
subjecting the carrier to an effective amount of heat, radiation, or both to reduce the adhesiveness of the adhesive material to allow for removal of at least one of the integrated circuit chips from the carrier; and
picking up and moving at least one of the integrated circuit chips using a tool configured to handle the integrated circuit chips.

2. The method of claim 1, wherein the wafer has a thickness of less than about 100 micrometers.

3. The method of claim 1, wherein said dicing the wafer is performed such that the support remains intact.

4. The method of claim 1, wherein said attaching the support to the back surface of the wafer comprises applying an adhesive between the back surface and the support that is capable of releasing the support when subjected to laser ablation.

5. The method of claim 1, wherein the releasable adhesive material comprises benzocyclobutene, a poly(arylene ether), a modified photoresist material, a modified polyimide material, thermal release tape, or a combination comprising at least one of the foregoing.
